(19) United States
(12) Patent Application Publication
(10) Pub. No.: US 2025/0191967 A1
(43) Pub. Date: Jun. 12, 2025

(54) METHOD FOR PRODUCING A SEMICONDUCTOR-ON-INSULATOR MULTILAYER STRUCTURE

(71) Applicant: Soitec, BERNIN (FR)

(72) Inventors: Isabelle Bertrand, BERNIN (FR); Romain Bouveyron, BERNIN (FR); Aymen Ghorbel, BERNIN (FR)

(21) Appl. No.: 18/845,522

(22) PCT Filed: Mar. 10, 2023
(86) PCT No.: PCT/FR2023/050325

§ 371 Date: Sep. 10, 2024

(30) Foreign Application Priority Data
Mar. 11, 2022 (FR) FR2202151

(51) Int. Cl. H01L 21/762; H10D 86/00

(52) U.S. Cl. CPC H01L 21/76251; H10D 86/201

(57) ABSTRACT

A method for producing a semiconductor-on-insulator structure comprises the steps of: —joining a support substrate with a donor substrate, the support substrate having an electrical resistivity greater than or equal to 500 Ω·cm and containing interstitial nitrogen and interstitial oxygen, the initial concentration of interstitial oxygen in the support substrate being between 15 and 25 old ppma, the donor substrate including a semiconductor layer, an electrically insulating layer being at the interface between the support substrate and the donor substrate; and—transferring the semiconductor layer onto the support substrate, the method further comprising a nucleation step comprising a heat treatment in order to precipitate part of the oxygen and nitrogen so as to form nuclei of oxygen and nitrogen precipitates, and a stabilization step comprising a heat treatment in order to grow the nuclei to a size of between 10 and 50 nm.

### CROSS-REFERENCE TO RELATED APPLICATIONS

This application is a national phase entry under 35 U.S.C. § 371 of International Patent Application PCT/FR2023/050325, filed Mar. 10, 2023, designating the United States of America and published as International Patent Publication WO 2023/170370 A1 on Sep. 14, 2023, which claims the benefit under Article 8 of the Patent Cooperation Treaty of French Patent Application Serial No. FR2202151, filed Mar. 11, 2022.

### TECHNICAL FIELD

This disclosure relates to a process for the manufacture of a multilayer structure of semiconductor-on-insulator type.

### BACKGROUND

Structures of semiconductor-on-insulator type are multilayer structures comprising a support substrate, which is generally made of a semiconductor material, such as silicon, an electrically insulating layer arranged on the support substrate, which is generally an oxide layer such as a silicon oxide layer, and a semiconductor layer arranged on the insulating layer, which is generally a silicon layer. Such structures are referred to as “Semiconductor-On-Insulator” structures, in particular, “Silicon-On-Insulator” (SOI) structures when the semiconductor material is silicon. The oxide layer is located between the substrate and the semiconductor layer. The oxide layer is then referred to as “buried” and is called “BOX” for “Buried OXide.” In the continuation of the text, the term “SOI” will be employed to denote generally structures of semiconductor-on-insulator type.

Such SOI structures can be obtained by a process involving the transfer of a single-crystal semiconductor layer resulting from a donor substrate onto the front face of the support substrate, an electrically insulating layer being at the interface between the transferred semiconductor layer and the support substrate.

For applications in the range of high frequencies, one issue lies in the manufacture of specific SOI structures, the performance qualities of which do not suffer from electrical losses brought about by flows of electrons from a conduction channel formed in or on the semiconductor layer to the support substrate. To this end, the process can, for example, comprise the use of a support substrate exhibiting a high electrical resistivity and optionally the combination of the support substrate with a trap-rich layer.

Another issue lies in the manufacture of SOI structures capable of enduring severe heat treatments without developing slip lines. Slip lines consist of planes of fracture where the crystal structure has become offset. Without obstacles, dislocations can propagate up to the surface of the slabs where they create steps of atomic planes or slip lines. During subsequent lithography stages, such steps cause problems, in particular, of misalignment of the lithography patterns (problem known to a person skilled in the art under the term “overlay”). In order to limit the appearance of these slip lines, the process can use, by way of support substrate, a substrate in which oxygen has been incorporated beforehand in the interstitial position at a relatively high concentration. Interstitial oxygen blocks the propagation of the dislocations and prevents, for this reason, the appearance of steps at the surface of slabs.

However, interstitial oxygen exhibits the disadvantage of generating thermal donors, which can cause the electrical resistivity of the support substrate to vary. Interstitial oxygen tends to cause the value of the electrical resistivity to fall. In point of fact, for applications in the range of the radiofrequencies, in particular, the electrical resistivity has to be controlled and kept stable, at a high value.

To overcome this disadvantage, one solution involves using a substrate weakly enriched in interstitial oxygen by way of support substrate. The concentration of interstitial oxygen of such substrates (commonly referred to as “low Oi”) is typically of between 6 and 10 old ppma, the unit old ppma denoting a “part per million of atoms” according to a former standardized measurement specification ASTM79. Such a concentration of interstitial oxygen is a relatively satisfactory compromise for large-sized electronic components manufactured from these substrates, making it possible to limit the number of slip lines while controlling the resistivity of the substrate.

However, as the trend is toward miniaturization, the development of slip lines, even in a very small amount, in small-sized electronic components is less and less tolerated. The use of weakly enriched substrates can result in a content of interstitial oxygen that is too low to achieve the expected performance qualities. The solution consisting simply in increasing the content of interstitial oxygen of the substrate is not satisfactory because an excessively high concentration of Oi no longer makes it possible to control the value of the electrical resistivity.

On the other hand, one solution that can be envisaged involves increasing the initial concentration of interstitial oxygen of the support substrate and, by the application of heat treatments, causing the interstitial oxygen to precipitate in the form of oxygen precipitates or defects known under the acronym BMD (Bulk Micro Defects).

The initial concentration of interstitial oxygen of the substrate is typically greater than 27 old ppma. The use of substrates highly enriched in interstitial oxygen (commonly referred to as “high Oi”) makes it possible to obtain a density on the order of 10¹⁰ oxygen precipitates or defects per cm³, the dimension of the precipitates being between 70 nm and 120 nm. The oxygen precipitates are then sufficiently big and numerous to, in the same way as the interstitial oxygen, block the propagation of the dislocations.

However, such a configuration does not make possible the control and the maintenance of the resistivity of the support substrate at a value that is stable and sufficiently high for applications in the radiofrequency range. In addition, if the oxygen precipitates are too numerous and too big, they generate localized mechanical stresses at the core of the material, which can cause an overall deformation of the substrate. The deformation of the substrate can also be the cause of problems of alignment of the lithography patterns.

### BRIEF SUMMARY

One aim of the present disclosure is to design a structure of semiconductor-on-insulator type such that the support substrate exhibits a good resistance to the subsequent development of slip lines while exhibiting a high and controlled electrical resistivity, and without, however, generating significant mechanical stresses within the support substrate that might cause its overall deformation.

The term “high electrical resistivity” is understood to mean, in the present text, an electrical resistivity of greater than or equal to 500 Ω·cm.

Another aim of this disclosure is to design a structure of semiconductor-on-insulator type that does not generate, during subsequent functionalization stages, the overlay problems known to a person skilled in the art, even for the manufacture of components applied in the field of high frequencies, the gate lengths of which are less than 65 nm, for example, less than or on the order of 22 nm.

To this end, the present disclosure provides a process for the manufacture of a multilayer structure of semiconductor-on-insulator type, comprising the following stages:
assembling of a support substrate exhibiting an electrical resistivity of greater than or equal to 500 Ω·cm and containing interstitial nitrogen and interstitial oxygen, the initial concentration of interstitial oxygen in the support substrate being between 15 old ppma and 25 old ppma (measured according to Standard ASTM79), and of a donor substrate for a semiconductor layer to be transferred, an electrically insulating layer being at the interface between the support substrate and the donor substrate,
transfer of the semiconductor layer onto the support substrate,
the process additionally comprising a nucleation stage suitable for precipitating, in a controlled way, at least a part of the interstitial oxygen and at least a part of the interstitial nitrogen, so as to form seeds of oxygen and nitrogen precipitates, and a stabilization stage suitable for causing the seeds of oxygen and nitrogen precipitates to grow to a size of between 10 nm and 50 nm.

The addition of interstitial nitrogen contributes a resistance to propagation of the dislocations without, however, degrading the resistivity of the support substrate. In addition, due to its affinity with oxygen, the addition of interstitial nitrogen helps in the precipitation of interstitial oxygen.

The addition of interstitial oxygen, in a controlled concentration intermediate between the concentrations of the “low Oi” and “high Oi” substrates, in conjunction with the addition of interstitial nitrogen, makes it possible to further improve the resistance to the subsequent development of slip lines, including for substrates having very slight thicknesses for which the overlay problems become critical.

The control of the size and of the concentration of the oxygen and nitrogen precipitates during the nucleation and growth stages also makes it possible to control the resistance to the subsequent development of slip lines by limiting the propagation of dislocations within the support substrate. In addition, by more or less fixing the interstitial nitrogen and the interstitial oxygen, the stages make it possible to control the resistivity of the support substrate, including the resistivity of highly resistive support substrates for applications in the range of high frequencies.

According to other characteristics of the disclosure, taken alone or in combination when combination is technically possible:
the process additionally comprises, before the assembling stage, the formation of a trap-rich layer on the support substrate, the trap-rich layer being arranged between the support substrate and the electrically insulating layer,
the formation of the trap-rich layer comprises the deposition of a layer of polycrystalline silicon on the support substrate,
the deposition of the layer of polycrystalline silicon is carried out after the stage of stabilization of the oxygen and nitrogen precipitates,
the initial concentration of interstitial nitrogen in the support substrate is between 10¹⁴ atoms/cm³ and 10¹⁵ atoms/cm³,
on conclusion of the stabilization stage, the support substrate comprises a concentration of oxygen and nitrogen precipitates of between 10⁷ precipitates·cm⁻³ and 10¹⁰ precipitates·cm⁻³, preferably a concentration of between 10⁸ precipitates·cm³ and 10⁹ precipitates·cm⁻³,
the nucleation stage and the stabilization stage each comprise a heat treatment, the temperature applied during the nucleation heat treatment being lower than the temperature applied during the stabilization heat treatment and the duration of the nucleation heat treatment being less than the duration of the stabilization heat treatment,
the nucleation stage comprises the application of a temperature of between 650° C. and 800° C., preferably a temperature of between 700° C. and 750° C., for a period of time of greater than one hour, preferably a period of time of two hours,
the stabilization stage comprises the application of a temperature of greater than 900° C., preferably a temperature of 950° C., for a period of time of greater than two hours, preferably a period of time of four hours,
the nucleation and stabilization stages are carried out directly the one following the other before the assembling stage.

The disclosure also relates to a substrate for microelectronics, optoelectronics and/or optics comprising, from its rear face to its front face, a support substrate, an electrically insulating layer and a semiconductor layer, characterized in that the support substrate is made of a semiconductor material exhibiting an electrical resistivity of greater than or equal to 500 Ω·cm and comprising oxygen and nitrogen precipitates exhibiting a size of between 10 nm and 50 nm, in a concentration of between 10⁷ precipitates·cm⁻³ and 10¹⁰ precipitates·cm⁻³.

According to other characteristics of the disclosure, taken alone or in combination when this is technically possible:
the substrate additionally comprises a trap-rich layer between the support substrate and the electrically insulating layer,
the residual concentration of interstitial oxygen in the support substrate is less than 15 old ppma, preferably less than 12 old ppma (measured according to Standard ASTM 79).

### BRIEF DESCRIPTION OF THE DRAWINGS

Other characteristics and advantages of the disclosure will emerge from the detailed description that will follow, with reference to the accompanying drawings, in which:

FIG. 1 represents a multilayer structure of semiconductor-on-insulator type according to the disclosure, the support substrate comprising oxygen and nitrogen precipitates (white circles), residual interstitial nitrogen (black crosses) and residual interstitial oxygen (black spots); and

FIGS. 2A to 2F represent an embodiment of the process according to the disclosure in which, starting from a support substrate comprising interstitial nitrogen and interstitial oxygen (FIG. 2A), a nucleation stage for the formation of seeds of oxygen and nitrogen precipitates (grey circles) (FIG. 2B), a stage of growth of the seeds to give stable oxygen and nitrogen precipitates (white circles) (FIG. 2C), an optional stage of formation of a trap-rich layer on the support substrate (FIG. 2D), a stage of arrangement of a donor substrate for a semiconductor layer to be transferred (FIG. 2E) on the support substrate (FIG. 2F) and a stage of transfer of the semiconductor layer, so as to obtain the multilayer structure of semiconductor-on-insulator type represented in FIG. 1, are successively carried out.

For reasons of readability, the drawings are not necessarily produced to scale.

### DETAILED DESCRIPTION

A first embodiment of the present disclosure is a multilayer structure of semiconductor-on-insulator type that exhibits a specific resistance to the propagation of dislocations and thus minimizes the formation of slip lines during back-end heat treatments. In addition, the electrical resistivity of the support substrate of the multilayer structure is stable during the heat treatments. By way of example, the multilayer structure in accordance with the disclosure can exhibit gate lengths of less than 65 nm, for example, on the order of 22 nm, while developing no or very few slip lines when a temperature on the order of 450° C. is applied to it for one hour. In addition, the support substrate of the multilayer structure can exhibit a target electrical resistivity of between 500 Ohm·cm and 5000 Ohm·cm while remaining stable. The multilayer structure of semiconductor-on-insulator type according to the disclosure has an application, for example, in the field of radiofrequencies for which highly resistive support substrates have a particular advantage.

FIG. 1 illustrates an embodiment of such a multilayer structure 1 according to the disclosure. The multilayer structure 1 successively comprises, from a rear face to a front face of the structure, a support substrate 2, an electrically insulating layer 3 and a semiconductor layer 4.

The support substrate 2 of the multilayer structure 1 is made of a highly resistive semiconductor material. The electrical resistivity of the support substrate is greater than or equal to 500 ohm·cm. A high electrical resistivity confers, on the support substrate, the ability to limit electrical losses and to improve the radiofrequency performance qualities of the structure.

The support substrate 2 of the multilayer structure 1 comprises oxygen and nitrogen precipitates 8, also known under the acronym BMD (Bulk Micro Defects). BMDs exhibit the property of blocking the propagation of dislocations that tend to develop when the multilayer structure 1 is subjected to heat treatments. BMDs thus make it possible to prevent the dislocations from going up to the surface of the multilayer structure 1, creating offsets of atomic planes there. Such offsets are, in particular, the cause of problems of alignment known to a person skilled in the art under the term of “overlay.”

The size of the oxygen and nitrogen precipitates 8 within the support substrate 2 of the multilayer structure 1 is between 10 nm and 50 nm, preferably between 40 nm and 50 nm. The range of sizes thus chosen constitutes an advantageous compromise making it possible to greatly limit the number of slip lines generated at the surface without, however, generating excessively high mechanical stresses in the material. This is because excessively small oxygen and nitrogen precipitates would not efficiently block the development of the dislocations. On the other hand, excessively large precipitates would risk generating high mechanical stresses within the material so that the material would be deformed. By this compromise, the abovementioned phenomenon of overlay is consequently minimized.

The concentration of the oxygen and nitrogen precipitates 8 within the support substrate 2 is between 10⁷ and 10¹⁰ precipitates per cm³, preferably between 10⁸ and 10⁹ precipitate per cm³. If the concentration of precipitates is less than 10⁷ precipitates per cm³, the oxygen and nitrogen precipitates are not sufficiently numerous to efficiently block the propagation of the dislocations. If the concentration of precipitates is greater than 10¹⁰ precipitates per cm³, the risk of generating mechanical stresses within the material becomes significant.

The size and the density of the oxygen and nitrogen precipitates 8 is measured by laser scattering tomography, known under the acronym LST.

The support substrate 2 can also comprise residual interstitial nitrogen 6 and residual interstitial oxygen 7, that is to say, not contributing to the precipitates 8. Just like the BMDs, the interstitial oxygen 7 and the interstitial nitrogen 6 oppose the propagation of the dislocations. However, the interstitial oxygen 7 can contribute to the generation of thermal donors, which risks bringing about an uncontrolled fall in the electrical resistivity. These thermal donors are generated when the multilayer structure 1 is subjected to back-end heat treatments, for example, when a temperature of between 375° C. and 450° C. is applied to the structure for a few minutes to one or two hours. This type of heat treatment is typically applied to the multilayer structure during the final annealing targeted at mending the defects generated during the final stages of manufacture of the chip, which are known to a person skilled in the art under the term “back end of line.” During this “passivation” annealing, the hydrogen present in the atmosphere of the furnace diffuses as far as the interfaces in order to mend pendent bonds.

To limit the phenomenon of generation of thermal donors, the concentration of residual interstitial oxygen 7 of the support substrate 2 is less than 15 ppma, preferably less than 12 ppma. This is because the lower the concentration of interstitial oxygen 7 within the support substrate 2, the better the control of the electrical resistivity of the support substrate 2 in the various applications of the multilayer structure 1.

As mentioned above, the term old ppma denotes a “part per million of atoms” according to a former standardized measurement specification ASTM 79.

The concentration of interstitial oxygen 7 is determined by virtue of a model for the generation of thermal donors: the heat treatment of 450° C. is applied to the substrate for one hour (known to a person skilled in the art under the acronym DGA for the term Donor Generation Anneal) and the electrical resistivity of the substrate is measured before and after the DGA heat treatment. A model makes it possible to connect the variation between the two measurements of the electrical resistivity, which is related to the generation of thermal donors, to the concentration of residual interstitial oxygen. The electrical resistivity is measured by SRP (Spreading Resistance Profile).

Optionally, the multilayer structure 1 also comprises a trap-rich layer 5, preferably made of polycrystalline silicon or of porous silicon, arranged between the support substrate 2 and the electrically insulating layer 3. This trap-rich layer makes it possible to trap the electrical charges that accumulate under the electrically insulating layer 3. The trap-rich layer 5 is particularly advantageous for radiofrequency applications of the multilayer structure 1.

The electrically insulating layer 3 can be an oxide layer, for example, a silicon oxide layer. Other materials, such as silicon nitride or silicon oxynitride, can be envisaged. The semiconductor layer 4 is a layer made of a semiconductor material, for example, a single-crystal silicon layer. In a non-limiting way, the semiconductor layer 4 can be replaced by an active layer of any other material, in particular, by a piezoelectric layer, such as, for example, lithium tantalate or lithium niobate. Other materials, such as gallium nitride, gallium arsenide or also indium phosphide, can be used.

### Manufacturing Process

A second embodiment of the present disclosure is a process for the manufacture of a multilayer structure as described above by precipitation of interstitial oxygen and of interstitial nitrogen so as to form oxygen and nitrogen precipitates within the support substrate of the multilayer structure.

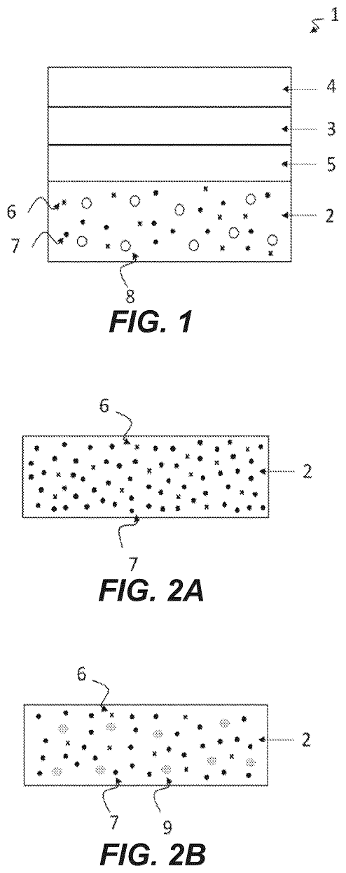

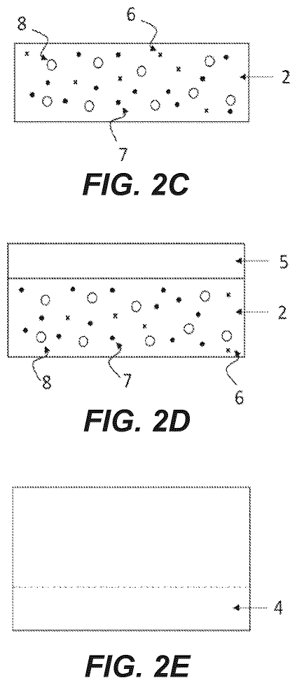

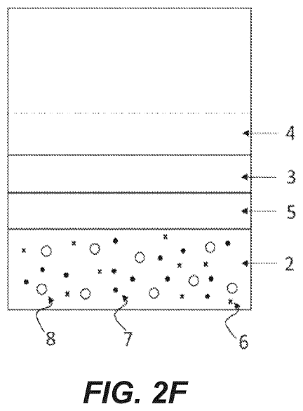

With reference to FIG. 2A, a support substrate 2 is initially provided. The support substrate 2 is made of a highly resistive semiconductor material, which initially comprises interstitial nitrogen 6 and interstitial oxygen 7. The support substrate 2 is, for example, a circular silicon slab with a diameter of 300 mm. The support substrate 2 can be prepared by pulling an ingot of the semiconductor material in an atmosphere of molecular oxygen and of nitrogen. The content of interstitial oxygen and nitrogen is generally controlled by the manufacturer of the ingot and indicated in the technical specifications of the substrates.

The addition of interstitial nitrogen 6 in addition to the interstitial oxygen 7 makes it possible to obtain a substrate that is more resistant to the propagation of the dislocations. The interstitial nitrogen 6, due to its affinity with oxygen, helps in the precipitation of the oxygen and nitrogen precipitates. For one and the same initial concentration of interstitial oxygen 7 of the support substrate 2, the addition of interstitial nitrogen 6 makes it possible to generate a greater density of precipitates. In addition, the precipitates generated in the presence of interstitial nitrogen 6 are smaller. The content of interstitial nitrogen 6 of the support substrate 2 is preferably between 10¹⁴ atoms/cm³ and 10¹⁵ atoms/cm³.

The concentration of interstitial oxygen 7 of the support substrate 2 is chosen to be greater than that of the substrates described as “low Oi,” so as to make possible the precipitation of the oxygen. Nevertheless, the concentration of interstitial oxygen 7 of the support substrate 2 is chosen to be less than that of the substrates described as “high Oi” in order to generate, during the precipitation, a lower density of precipitates than starting from a “high Oi” substrate. In addition, the dimensions of the precipitates are smaller than those of the precipitates generated within a “high Oi” substrate. In addition, on conclusion of the precipitation, the concentration of residual interstitial oxygen is lower than in the “high Oi” substrates.

In this way, a substrate is obtained that exhibits a better resistance to the propagation of the dislocations than a “low Oi” substrate. The density and the dimension of the precipitates generate less in the way of mechanical stresses than those obtained starting from a “high Oi” substrate. The low concentration of residual interstitial oxygen makes it possible to limit the generation of thermal donors and thus to better control the resistivity of the substrate.

In other words, the concentration of interstitial oxygen 7 of the support substrate 2 is intermediate between the concentration of interstitial oxygen of the “low Oi” substrates and the concentration of interstitial oxygen of the “high Oi” substrates. The concentration of interstitial oxygen 7 of the support substrate 2 is preferably between 15 old ppma and 25 old ppma.

Subsequently, a preferred embodiment of the process is described. With reference to FIGS. 2B to 2F, this process comprises at least the following successive stages:
a nucleation stage, so as to create seeds 9 of oxygen and nitrogen precipitates within the support substrate 2 (c),
a stabilization stage, so as to cause the seeds of oxygen and nitrogen precipitates 8 within the support substrate 2 to grow (d),
an optional stage of formation of a trap-rich layer 5 on the support substrate 2 (e),
a stage of arrangement of a donor substrate for a semiconductor layer 4 to be transferred on the support substrate 2, an electrically insulating layer 3 being at the interface between the support substrate 2 and the layer 4 to be transferred (a),
a stage of transfer of the semiconductor layer 4 (b).

### Nucleation Stage (c) and Stabilization Stage (d)

During the nucleation stage (c), the interstitial nitrogen 6 and the interstitial oxygen 7 diffuse within the material of the support substrate 2. In addition, the bonds between some of the atoms of the semiconductor material break, while new bonds are formed between the atoms of the semiconductor material and the nitrogen, between the atoms of the semiconductor material and the oxygen, and between the nitrogen and the oxygen, so as to form seeds 9 of oxygen and nitrogen precipitates and to obtain the structure represented in FIG. 2B.

During the stabilization stage (d), some seeds 9 of nitrogen and oxygen precipitates generated during the nucleation stage (c) will grow in the form of grains 8′, others (the smallest) will dissolve. The growth of the grains 8′ will make it possible to stabilize the grains 8′ so that they will have less of a tendency to redissolve under the effect of the subsequent treatments, particularly during heat treatments. The structure obtained on conclusion of the stabilization stage (d) is represented in FIG. 2C.

The nucleation stage (c) and the stabilization stage (d) each comprise a heat treatment, the parameters of which are fixed so as to obtain, on conclusion of stage (d), due to the presence of interstitial nitrogen 6 and of interstitial oxygen 7 in a concentration intermediate between “low Oi” and “high Oi,” oxygen and nitrogen precipitates 8, the size of which is between 10 nm and 50 nm, preferably greater than 40 nm. Thus, the process in accordance with the disclosure generates smaller precipitates than those obtained starting from a “high Oi” substrate. As mentioned above, this range of sizes of precipitates represents a good compromise to obtain a better resistance to the propagation of the dislocations than in the “low Oi” substrates while observing less in the way of mechanical stresses than in the “high Oi” substrates.

In addition, the parameters of the nucleation stage (c) and of the stabilization stage (d) are preferably fixed so as to generate a density of nitrogen and oxygen precipitates 8 of between 10⁷ and 10¹⁰ precipitates per cm³, preferably of between 10⁸ and 10⁹ precipitates per cm³, i.e., a lower density of defects than that obtained starting from a “high Oi” substrate. To obtain precipitates in such a range of concentrations is made possible by the presence of interstitial nitrogen 6 and by the initial concentration of interstitial oxygen 7 of the support substrate 2. As mentioned above, this range of concentrations of precipitates represents a good compromise in order to obtain a good resistance to the propagation of the dislocations while limiting the stresses.

The nucleation stage (c) comprises, for example, a heat treatment during which a temperature of between 650° C. and 800° C., preferably a temperature of between 700° C. and 750° C., is applied to the support substrate 2 for a period of time of greater than one hour, preferably a period of time of two hours.

The temperature of the heat treatment employed during the nucleation stage (c) has to be strictly less than 1000° C. This is because a temperature greater than or equal to 1000° C. would result in an excessively high diffusion of the interstitial nitrogen 6 out of the support substrate 2. A temperature of less than 800° C. makes it possible to limit even more the diffusion of the interstitial nitrogen 6 out of the support substrate 2.

The stabilization stage (d) comprises, for example, a heat treatment during which a temperature of greater than 900° C. and strictly less than 1000° C. is applied to the support substrate 2 for a period of time of greater than two hours, preferably a period of time of four hours.

The temperature of the heat treatment employed during the stabilization stage (d) has to be strictly less than 1000° C. This is because a temperature greater than or equal to 1000° C. would result in the redissolution of the seeds 9 of oxygen and nitrogen precipitates generated during the nucleation stage (c) and the diffusion of the interstitial nitrogen 6 out of the support substrate 2, so that it would not be possible to obtain the oxygen and nitrogen precipitates 8.

The temperature of the heat treatment employed during the stabilization stage (d) is preferably greater than 900° C. The stabilization stage (d) thus makes it possible to obtain stable precipitates during a heat treatment up to a temperature on the order of 1200° C. applied for more than one hour. The back-end processes that the structure subsequently must be subjected to generally exhibit a lower thermal budget, so that the precipitates are not liable to disappear during these subsequent treatments.

### Stage of Formation of a Trap-Rich Layer (e)

Optionally, with reference to FIG. 2D, during a stage (e), a trap-rich layer 5 is formed on the support substrate 2, between the support substrate 2 and the electrically insulating layer 3. As mentioned above, the trap-rich layer is particularly advantageous in radiofrequency applications because it makes it possible to trap the charges that accumulate under the electrically insulating layer 3. The trap-rich layer can be made of polycrystalline silicon.

During the stage of formation of the trap-rich layer (e), the support substrate 2 must not be brought to a temperature of greater than 1200° C. for more than one or two hours. This is because, above 1200° C., the oxygen and nitrogen precipitates 8 can redissolve and the interstitial nitrogen 6 diffuses out of the material of the support substrate 2.

The stage of formation of the trap-rich layer comprises, for example, a chemical vapor deposition (CVD) or an epitaxial deposition on the support substrate at a temperature that can be between 600° C. and 1100° C. according to the technique used, in the presence or in the absence of a seed.

Optionally, the trap-rich layer can be formed before the nucleation heat treatment.

This is because the abovementioned nucleation stage (c) and stabilization stage (d) are carried out with sufficiently low thermal budgets to avoid or at the very least limit the recrystallization of the polycrystalline silicon of the trap-rich layer 5.

Preferably, the trap-rich layer 5 is formed after the nucleation heat treatment (c), indeed, even after the stabilization heat treatment (d), in order to prevent the structure of this layer from being modified during these treatments.

### Stage of Assembling of a Donor Substrate on the Support Substrate (a) and Stage of Transfer of a Semiconductor Layer (b)

A stage (a) of assembling of a donor substrate for a semiconductor layer 4 to be transferred on the support substrate 2 is carried out, an electrically insulating layer 3 being at the interface between the support substrate 2 and the semiconductor layer 4 to be transferred. A stage (b) of transfer of the semiconductor layer 4 to be transferred is subsequently carried out so as to obtain the multilayer structure 1 represented in FIG. 1.

The donor substrate for the semiconductor layer 4 is provided in the form of a slab, for example, a circular slab having the same dimension as the support substrate 2. The donor substrate comprises a semiconductor material, for example, single-crystal silicon.

The layer transfer can, for example, be carried out according to a Smart Cut™ process. In this case, stage (a) comprises the following substages:
provision of a donor substrate for the single-crystal semiconductor layer 4 represented in FIG. 2E,
formation of a weakened zone in the donor substrate, so as to delimit the semiconductor layer 4 to be transferred (dotted lines of FIG. 2E),
bonding of the donor substrate to the support substrate 2, the electrically insulating layer 3 being at the interface between the support substrate 2 and the donor substrate, so as to obtain the structure represented in FIG. 2F.

Stage (b) comprises the detachment of the donor substrate at the weakened zone, so as to transfer the semiconductor layer 4 and to form the multilayer structure 1 represented in FIG. 1.

The weakened zone can be created by co-implantation of helium atoms and of hydrogen atoms in the donor substrate for the semiconductor layer. Alternatively, the weakened zone is created by implantation of hydrogen or helium atoms alone.

The detachment along the weakened zone can be triggered by a mechanical action, a contribution of thermal energy, optionally in combination, or any other suitable means.

Alternatively to the Smart Cut™ process, stage (a) can comprise the bonding of the donor substrate for the semiconductor layer 4 to be transferred to the support substrate 2, the electrically insulating layer 3 being at the interface, while stage (b) can comprise the thinning of the donor substrate from its face opposite the face bonded to the support substrate 2 until the thickness desired for the semiconductor layer 4 is obtained.

The electrically insulating layer 3 is, for example, an oxide layer, such as a silicon oxide layer. The electrically insulating oxide layer 3 can be formed on the support substrate 2 optionally covered with the trap-rich layer 5 or on the donor substrate for the semiconductor layer 4 prior to the bonding of the donor substrate to the support substrate.

Throughout the stage of assembling of the donor substrate on the support substrate (a) and the stage (b) of transfer of the semiconductor layer 4, the support substrate 2 must not be brought to temperature greater than 1200° C. for more than one hour in order not to bring about the redissolution of the oxygen and nitrogen precipitates 8.

If the multilayer structure comprises a trap-rich layer 5 made of a polycrystalline material, the temperature applied must not exceed 1100° C. for more than two hours in order not to bring about the recrystallization of the layer.

According to alternative embodiments of the process according to the disclosure, the nucleation stage (c) and the stabilization stage (d) can be carried out after the stage (a) of arrangement of the donor substrate on the support substrate 2 optionally covered with the trap-rich layer 5 or after the stage (b) of transfer of the semiconductor layer 4. According to each of these embodiments, each stage (a), (b), (c), (d) and (e) is furthermore carried out as described above.

However, the stages preceding the nucleation stage (c) and the stabilization stage (d) must not comprise the application of a temperature of greater than or equal to 1000° C. over a period of time on the order of one hour to several hours. This is because a temperature of greater than or equal to 1000° C. would bring about the diffusion of the interstitial nitrogen 6 out of the support substrate, so that the oxygen and nitrogen precipitates 8 might not be formed.

According to yet other embodiments of the process according to the disclosure, the nucleation stage (c) and the stabilization stage (d) are not consecutive, so that at least one stage from stages (a), (b) and (e) can be put between the nucleation stage (c) and the stabilization stage (d). According to each of these embodiments, each stage (a), (b), (c), (d) and (e) is furthermore carried out as described above.

When stages (c) and (d) are not consecutive, the stages preceding the stabilization stage (d) must not comprise the application of a temperature of greater than or equal to 1000° C. over a period of time on the order of one hour to several hours in order not to bring about the diffusion of the interstitial nitrogen 6 out of the support substrate 2 and the redissolution of the seeds 9 of oxygen and nitrogen precipitates generated during the nucleation stage (c).

Finally, whatever the embodiment chosen, the stages subsequent to the stabilization stage (d) must not comprise the application of a temperature of greater than 1200° C. for more than one hour in order not to bring about the redissolution of the oxygen and nitrogen precipitates 8.

1. A method of manufacturing a semiconductor-on-insulator multilayer structure, comprising the following stages:
(a) assembling a support substrate with a donor substrate, the support substrate comprising a semiconductor material exhibiting an electrical resistivity of greater than or equal to 500 Ω·cm and containing interstitial nitrogen and interstitial oxygen, an initial concentration of interstitial oxygen in the support substrate being between 15 old ppma and 25 old ppma (measured according to Standard ASTM79), the donor substrate including a semiconductor layer to be transferred, an electrically insulating layer being at an interface between the support substrate and the donor substrate;
transferring the semiconductor layer onto the support substrate;
performing a nucleation heat treatment for precipitating, in a controlled way, at least a part of the interstitial oxygen and at least a part of the interstitial nitrogen, so as to form seeds of oxygen and nitrogen precipitates; and
(d) performing a stabilization heat treatment for causing the seeds of oxygen and nitrogen precipitates to grow to a size of between 10 nm and 50 nm.

2. The method of claim 1, further comprising before the stage (a), forming a trap-rich layer on the support substrate, the trap-rich layer being located between the support substrate and the electrically insulating layer after the stage (a).

3. The method of claim 2, wherein forming the trap-rich layer comprises depositing a layer of polycrystalline silicon on the support substrate.

4. The method of claim 3, wherein the depositing of the layer of polycrystalline silicon is carried out after the stage (d).

5. The method of claim 1, wherein an initial concentration of interstitial nitrogen in the support substrate is between 10¹⁴ atoms/cm³ and 10¹⁵ atoms/cm³.

6. The method of claim 1, wherein, on conclusion of the stage (d), the support substrate comprises a concentration of oxygen and nitrogen precipitates of between 10⁷ precipitates·cm⁻³ and 10¹⁰ precipitates·cm⁻³.

7. The method of claim 1, wherein a temperature applied during the nucleation heat treatment of the stage (c) is lower than a temperature applied during the stabilization heat treatment of the stage (d) and a duration of the nucleation heat treatment of the stage (c) is less than a duration of the stabilization heat treatment of the stage (d).

8. The method of claim 1, wherein the stage (c) comprises application of a temperature of between 650° C. for a period of time of greater than one hour.

9. The method of claim 1, wherein the stage (d) comprises application of a temperature of greater than 900° C. for a period of time of greater than two hours.

10. The method of claim 1, wherein the stage (c) and the stage (d) are carried out directly with one following the other before the stage (a).

11. A semiconductor-on-insulator multilayer structure comprising, from a rear face to a front face thereof, a support substrate, an electrically insulating layer and a semiconductor layer, wherein the support substrate comprises a semiconductor material exhibiting an electrical resistivity greater than or equal to 500 Ω·cm and comprising oxygen and nitrogen precipitates exhibiting a size between 10 nm and 50 nm, in a concentration of between 10⁷ precipitates·cm⁻³ and 10¹⁰ precipitates·cm⁻³.

12. The multilayer structure of claim 11, further comprising a trap-rich layer between the support substrate and the electrically insulating layer.

13. The multilayer structure of claim 11, wherein a residual concentration of interstitial oxygen in the support substrate is less than 15 old ppma, preferentially less than 12 old ppma (measured according to Standard ASTM 79).

14. The method of claim 5, wherein, on conclusion of the stage (d), the support substrate comprises a concentration of oxygen and nitrogen precipitates of between 10⁸ precipitates·cm⁻³ and 10⁹ precipitates·cm⁻³.

15. The method of claim 7, wherein the stage (c) comprises application of a temperature of between 700° C. and 750° C. for a period of time of two hours.

16. The method of claim 8, wherein the stage (d) comprises application of a temperature of 950° C. for a period of time of four hours.

17. The method of claim 4, wherein an initial concentration of interstitial nitrogen in the support substrate is between 10¹⁴ atoms/cm³ and 10¹⁵ atoms/cm³.

18. The method of claim 17, wherein, on conclusion of the stage (d), the support substrate comprises a concentration of oxygen and nitrogen precipitates of between 10⁷ precipitates·cm⁻³ and 10¹⁰ precipitates·cm⁻³.

19. The method of claim 18, wherein a temperature applied during the nucleation heat treatment of the stage (c) is lower than a temperature applied during the stabilization heat treatment of the stage (d) and a duration of the nucleation heat treatment of the stage (c) is less than a duration of the stabilization heat treatment of the stage (d).

20. The method of claim 19, wherein the stage (c) comprises application of a temperature of between 650° C. and 800° C. for a period of time of greater than one hour, and the stage (d) comprises application of a temperature of greater than 900° C. for a period of time of greater than two hours.
